(19) United States
(12) Patent Application Publication
(10) Pub. No.: US 2024/0396462 A1
(43) Pub. Date: Nov. 28, 2024

(54) SYNCHRONOUS RECTIFIER CONTROL TECHNIQUES

(71) Applicant: Resonant Link, Inc., South Burlington, VT (US)

(72) Inventors: Milovan Kovacevic, Palo Alto, CA (US); Aaron Stein, Essex, VT (US); Grayson Zulauf, Palo Alto, CA (US); Phyo Aung Kyaw, Winooski, VT (US)

(73) Assignee: Resonant Link, Inc., South Burlington, VT (US)

(21) Appl. No.: 18/794,731

(22) Filed: Aug. 5, 2024

Related U.S. Application Data
(63) Continuation of application No. PCT/US2023/012393, filed on Feb. 6, 2023.
(60) Provisional application No. 63/307,346, filed on Feb. 7, 2022.

(51) Int. Cl. H02M 3/335; G01R 15/18; H02M 1/00

(52) U.S. Cl. CPC H02M 3/33592; G01R 15/181; H02M 1/0009; H02M 1/0058

(57) ABSTRACT

Control circuitry for a synchronous rectifier includes a sensor configured to sense a current through a power switch of the synchronous rectifier or a voltage across the power switch; a phase compensation network coupled to the output of the sensor, the phase compensation network being configured to shift a phase of the output of the sensor in a leading direction to generate a phase-shifted sense signal; and drive circuitry configured to control switching of the power switch based on the phase-shifted sense signal.

### RELATED APPLICATION

This application is a Continuation of International Patent Application Serial No. PCT/US2023/012393, filed Feb. 6, 2023, titled “SYNCHRONOUS RECTIFIER CONTROL TECHNIQUES”, which claims the benefit of U.S. Provisional Application Ser. No. 63/307,346, filed Feb. 7, 2022 titled “SYNCHRONOUS RECTIFIER CONTROL TECHNIQUES,” each of which is incorporated herein by reference in its entirety.

### FIELD OF THE DISCLOSURE

The technology disclosed herein relates to power electronics, and in particular to synchronous rectifiers and control techniques for synchronous rectifiers.

### BACKGROUND

Rectifiers are electrical circuits that convert a signal of alternating polarity into a signal having a single polarity. Some rectifiers may use an electrical arrangement of diodes to convert alternating current to direct current. Synchronous rectifiers are rectifiers that substitute the diodes for switches.

### SUMMARY

Some aspects relate to control circuitry for a synchronous rectifier, the control circuitry comprising: a sensor configured to sense a current through a power switch of the synchronous rectifier, a voltage across the power switch, or a current or voltage related to the current through the power switch or the voltage across the power switch; a phase compensation network coupled to the output of the sensor, the phase compensation network being configured to shift a phase of the output of the sensor in a leading direction to generate a phase-shifted sense signal; and drive circuitry configured to control switching of the power switch based on the phase-shifted sense signal.

The sensor may comprise a current sensor and the drive circuitry may be configured to control turn-off timings for the power switch based on the phase-shifted sense signal.

The control circuitry may further comprise comparison circuitry configured to compare the phase-shifted sense signal to a threshold voltage, and to control the drive circuitry based on the comparison between the phase-shifted sense signal and the threshold voltage.

The comparison circuitry may comprise a comparator.

The phase shift produced by the phase compensation network may be selected to compensate for a delay in a signal chain driving the power switch.

The output may be a first output, the control circuitry may further comprise a resistor, the resistor comprising a first end and a second end. The first end may be coupled to a second output of the phase compensation network.

The comparison circuitry may comprise a comparator, the comparator comprising a first comparator input, a second comparator input, and a comparator output, the first comparator input being coupled to the first end of the resistor, the second comparator input being coupled to a terminal configured to receive a threshold voltage, the comparator output being coupled to an input of the drive circuitry.

The sensor may comprise a current sense transformer or a Rogowski coil.

Some aspects relate to control circuitry for a synchronous rectifier, the control circuitry comprising: a sensor configured to sense a current through a power switch of the synchronous rectifier, a voltage across the power switch, or a current or voltage related to the current through the power switch or the voltage across the power switch, to produce a sense signal; comparison circuitry configured to compare the sense signal to a non-zero threshold value; a pulse generator configured to generate a pulse in response to an output of the comparison circuitry; and drive circuitry configured to control switching of the power switch in response to the pulse.

The non-zero threshold value may be selected to compensate for a delay in a signal chain driving the power switch.

The pulse generator may comprise a single-shot circuit.

The drive circuitry may be configured to control the power switch to turn on in response to the pulse.

A first input of the comparison circuitry may be coupled to a first output of the sensor; a second input of the pulse generation circuitry may be coupled to the output of the comparison circuitry, which is a second output; a third input of the drive circuitry may be coupled to a third output of the pulse generation circuitry; and a fourth output of the drive circuitry may be coupled to the power switch.

The control circuitry may further comprise a resistor with a first end and a second end, the first end coupled to the first output of the sensor and the first input of the comparison circuitry, and the second end coupled to a fourth input of the sensor.

The sensor may be a current sensor.

The current sensor may comprise a current sense transformer or a Rogowski coil.

Some aspects relate to wireless power receiver comprising the control circuitry of any preceding claim and the synchronous rectifier.

Some aspects relate to a method of controlling a synchronous rectifier, the method comprising: sensing a current through a power switch of the synchronous rectifier, a voltage across the power switch, or a current or voltage related to the current through the power switch or the voltage across the power switch, to produce a sense signal; shifting a phase of the sense signal in a leading direction to produce a phase shifted sense signal; and controlling switching of the power switch based on the phase shifted sense signal.

Some aspects relate to a method of controlling a synchronous rectifier, the method comprising: sensing a current through a power switch of the synchronous rectifier, a voltage across the power switch, or a current or voltage related to the current through the power switch or the voltage across the power switch, to produce a sense signal; comparing the sense signal to a non-zero threshold value; generating a pulse when the sense signal falls below the non-zero threshold value; and controlling switching of the power switch in response to the pulse.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques and devices described herein.

FIG. 1 is a schematic illustration of an example power conversion system including an example synchronous rectifier, which includes example control circuitry, to convert an input to an output.

FIG. 2A is a schematic illustration of an example implementation of a portion of the example control circuitry of FIG. 1.

FIG. 2B depicts example waveforms associated with shifting phases of current measurements in accordance with the teachings of this disclosure.

FIG. 2C is a timing diagram that depicts example waveforms associated with an example synchronous rectifier technique based on adjusting a threshold used for switching a power switch.

FIG. 3 is a schematic illustration of another example power conversion system including an example synchronous rectifier, which includes example control circuitry, to convert an input to an output.

FIG. 4 is a schematic illustration of an example implementation of a portion of the example control circuitry of FIG. 3.

FIG. 5 is a schematic illustration of an example implementation of a wireless power receiver in accordance with the teachings of this disclosure.

FIG. 6 is a flowchart of an example method to control switching of a power switch of the example synchronous rectifier of FIG. 1.

FIG. 7 is a flowchart of an example method to control switching of a power switch of the example synchronous rectifier of FIG. 3.

### DETAILED DESCRIPTION

Rectifiers convert a signal of alternating polarity into a signal having a single polarity. Rectifiers may be used to convert alternating current (AC) to direct current (DC). Rectifiers that are implemented by diodes, such as diode or diode-based rectifiers, may have significant power losses due to the voltage drop across the diodes. A synchronous rectifier can improve efficiency of a power conversion system by substituting diodes for switches having a lower on-state voltage drop. Synchronous rectifiers may be controlled such that the timing of turning on/off the switches mimics the timing of conducting switching in the diodes of a diode rectifier. Synchronous rectifiers may be particularly useful for providing high efficiency when rectifying low voltage signals. Synchronous rectification is more challenging at high frequencies because the timings are shorter, and delays can cause high losses (i.e., high power losses) and reduced power conversion efficiency. However, the techniques disclosed herein may be used for signals of any suitable voltage and frequency.

Synchronous rectification may be performed by sensing the switch current and/or voltage, which may be performed directly at the switch or indirectly by measuring another current and/or voltage in the system related to, corresponding to, or representative of the switch current and/or voltage. The timing of turning on/off the switches may be determined based on the sensed current and/or voltage. For example, a switch may be turned on when the voltage across the switch is at or near zero (referred to as zero voltage switching, or ZVS), and a switch may be turned off when the current through the switch is at or near zero (referred to as zero current switching, or ZCS).

The inventors have recognized and appreciated that the sensing circuit, control circuit, and switch drive circuitry introduce delays from signal generation to switch activation, which result in increased power losses due to a delayed reaction with respect to ideal or optimal ZVS or ZCS switching times. It may be desirable to avoid such power losses.

Examples disclosed herein include synchronous rectifier control techniques to reduce power losses by controlling the switches of the synchronous rectifier to switch at times that are closer to ideal or optimal ZVS or ZCS switching times.

In some disclosed examples, a phase compensation network may compensate delay in a signal chain (e.g., a switch control signal chain) of a synchronous rectifier. For example, a phase compensation network may adjust or change sensed current in a phase leading direction to compensate delay in the signal chain for the sensed current. Such a phase compensation network may be used to obtain accurate turn-off timings for switching the rectifier active switches using ZVS. Advantageously, the amount of phase compensation may be controlled to match the delay in the signal chain and thereby reduce power losses associated with synchronous rectification.

In some disclosed examples, the switch turn-on timing of a power switch of the synchronous rectifier may be adjusted or changed. For example, the switch turn-on timing may be changed by adjusting a threshold (e.g., a threshold voltage) used for turning on the switch. For example, rather than waiting for a zero-crossing of the voltage, such as in ZVS, the power switch may be turned on at a small positive voltage value. Advantageously, turning on the power switch “early” relative to the measured zero crossing of the voltage may thus compensate for the delay introduced in the measurement and control signal chain.

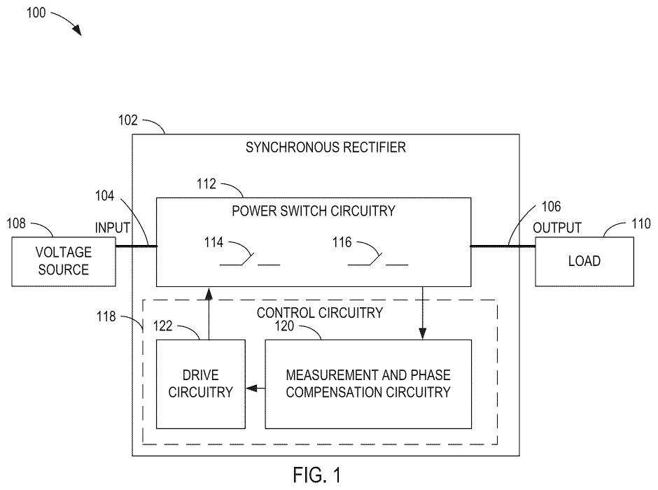

FIG. 1 is a schematic illustration of an example power conversion system 100 including an example synchronous rectifier 102. The synchronous rectifier 102, and/or, more generally, the power conversion system 100, may convert an example input 104 to an example output 106. For example, the input 104 may be a voltage input (or input voltage), such as an alternating current (AC) voltage, from a voltage source 108. In some examples, the voltage source 108 may be a resonant coil, an inverter (e.g., a power inverter), a capacitor, an inductor and capacitor circuit (e.g., an LC circuit, an LC structure, etc.), etc., and/or any combination(s) thereof. For example, the voltage source 108 may provide and/or output an AC voltage to the synchronous rectifier 102.

In some examples, the output 106 may be a voltage output (or output voltage), such as a direct current (DC) voltage. The output 106 of the illustrated example is provided to an example load 110 (e.g., an electrical load, an electromechanical load, etc.). For example, the load 110 may be a battery (e.g., a rechargeable battery, a lithium-ion battery, etc.), battery charger, an electromechanical actuator, one or more analog circuits, one or more digital circuits, one or more programmable processors (e.g., microprocessors, central processing units (CPUs), field programmable gate arrays (FPGAs), graphics processing units (GPUs), etc.), a power converter (e.g., a DC-to-DC (DC/DC) power converter), etc., and/or any combination(s) thereof.

In the illustrated example of FIG. 1, output(s) of the voltage source 108 is/are coupled to respective input(s) of the synchronous rectifier 102. For example, the output(s) and/or the input(s) may be implemented by connector(s), pin(s), socket(s), terminal(s), etc., and/or any combination(s) thereof. Output(s) of the synchronous rectifier 102 is/are coupled to respective input(s) of the load 110.

The synchronous rectifier 102 rectifies and/or converts the input 104, such as an AC voltage, to the output 106, such as a DC voltage, via example power switch circuitry 112. The power switch circuitry 112 includes a plurality of example switches 114, 116 configured or structured in an arrangement (e.g., a full-bridge rectifier configuration/arrangement, a half-bridge rectifier configuration/arrangement, etc.) to convert the input 104 to the output 106. The switches 114, 116 include first example switches 114 and second example switches 116. Alternatively, the first switches 114 and/or the second switches 116 may respectively include one switch. Generally, the first switches 114 may be turned on (i.e., conduct or be switched closed) and the second switches 116 may be turned off (i.e., not conduct or be switched open) during a first switching time during which a first polarity (e.g., a negative polarity, a positive polarity, etc.) of the voltage of the input 104 is detected. Similarly, the first switches 114 may be turned off and the second switches 116 may be turned on during a second switching time during which a second polarity (e.g., a negative polarity, a positive polarity, etc.) of the voltage of the input 104 is detected.

In some examples, one(s) of the first switches 114 and/or one(s) of the second switches 116 is/are field-effect transistors (FETs) such as power FETs, metal-oxide-semiconductor field-effect transistors (MOSFETs) (e.g., p-channel MOSFETs, n-channel MOSFETs, etc.), etc., and/or any combination(s) thereof. In some examples, one(s) of the first switches 114 and/or one(s) of the second switches 116 is/are bipolar junction transistors (BJTs) (e.g., NPN BJTs, PNP BJTs, etc.), insulated-gate bipolar junctions (IGBTs), etc., and/or any combination(s) thereof.

In the illustrated example of FIG. 1, example control circuitry 118 controls switching of the switches 114, 116, and/or, more generally, the power switch circuitry 112. For example, the control circuitry 118 may control turning on or off one or more of the first switches 114 and/or the second switches 116 based on a current and/or a voltage associated with the one or more of the first switches 114, the one or more of the second switches 116, or a different switch of the power switch circuitry 112.

In the illustrated example of FIG. 1, input(s) of the power switch circuitry 112 is/are coupled to output(s) of the voltage source 108 and output(s) of the control circuitry 118. Output(s) of the power switch circuitry 112 is/are coupled to input(s) of the load 110 and input(s) of the control circuitry 118.

The control circuitry 118 includes example measurement and phase compensation circuitry 120 to measure one or more currents and/or one or more voltages of the power switch circuitry 112. The measured or sensed current and/or voltage may be used for switch control of the power switch circuitry 112. For example, the measurement and phase compensation circuitry 120 may include a sensor, such as a current sensor, to measure and/or sense a current of the power switch circuitry 112. In some examples, the measurement and phase compensation circuitry 120 may include a different type of sensor, such as a voltage sensor, to measure and/or sense a voltage of the power switch circuitry 112.

The measurement and phase compensation circuitry 120 may generate a sensed signal that corresponds to the sensed current or voltage. The measurement and phase compensation circuitry 120 may shift a phase of the sensed signal to compensate for delays in a signal chain of the synchronous rectifier 102. For example, the synchronous rectifier 102 may include a signal chain that includes the power switch circuitry 112, the measurement and phase compensation circuitry 120, example drive circuitry 122 of the control circuitry 118, and/or portion(s) thereof. For example, the signal chain may include portion(s) of the synchronous rectifier 102 from signal generation (e.g., sensing a current and/or voltage of one(s) of the switches 114, 116) to switch activation (e.g., turning on/off one(s) of the switches 114, 116 based on the sensed current). A delay in a signal chain of the synchronous rectifier 102 may be a propagation delay from a first time at which a current or voltage of the power switch circuitry 112 is measured to a second time at which one(s) of the switches 114, 116 are turned on or off based on the measured current or voltage. The measurement and phase compensation circuitry 120 may shift a phase of a sensed current or voltage in a direction, such as a leading direction, to reduce and/or mitigate an effect of the propagation delay on a power efficiency of the synchronous rectifier 102.

The control circuitry 118 includes the drive circuitry 122 to control switching, such as turning on or off, one(s) of the switches 114, 116. In some examples, the drive circuitry 122 controls switching of one(s) of the switches 114, 116 in response to signals generated by the measurement and phase compensation circuitry 120.

In the illustrated example of FIG. 1, input(s) of the measurement and phase compensation circuitry 120 is/are coupled to respective output(s) of the power switch circuitry 112. Output(s) of the measurement and phase compensation circuitry 120 is/are coupled to respective input(s) of the drive circuitry 122. Output(s) of the drive circuitry 122 is/are coupled to respective input(s) of the power switch circuitry 112.

In example operation, the drive circuitry 122 may turn on the first switches 114 (with the second switches 116 turned off) during a first time period in which a first polarity of the voltage source 108 is present. The measurement and phase compensation circuitry 120 may sense a current associated with one(s) of the first switches 114. The measurement and phase compensation circuitry 120 may adjust a phase of the sensed current in a leading direction to compensate for delays in the signal chain of the synchronous rectifier 102, or portion(s) thereof. For example, the measurement and phase compensation circuitry 120 may adjust the phase of the sensed current to generate a phase shifted sensed current. The measurement and phase compensation circuitry 120 may generate a signal representative of or corresponding to the phase shifted sensed current. The measurement and phase compensation circuitry 120 may output the signal to the drive circuitry 122 to cause the drive circuitry 122 to control one(s) of the switches 114, 116 based on the signal, and/or, more generally, the phase shifted sensed current. For example, the drive circuitry 122 may turn on the second switches 116 (with the first switches 114 turned off) during a second time period, after the first time period, in which a second polarity of the voltage source 108 is present.

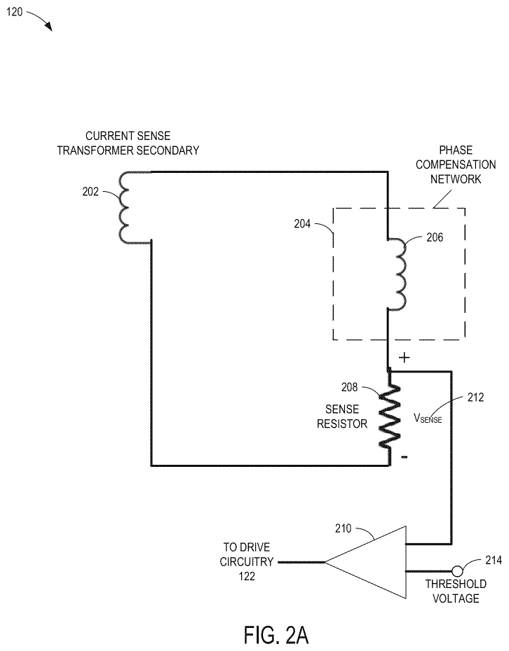

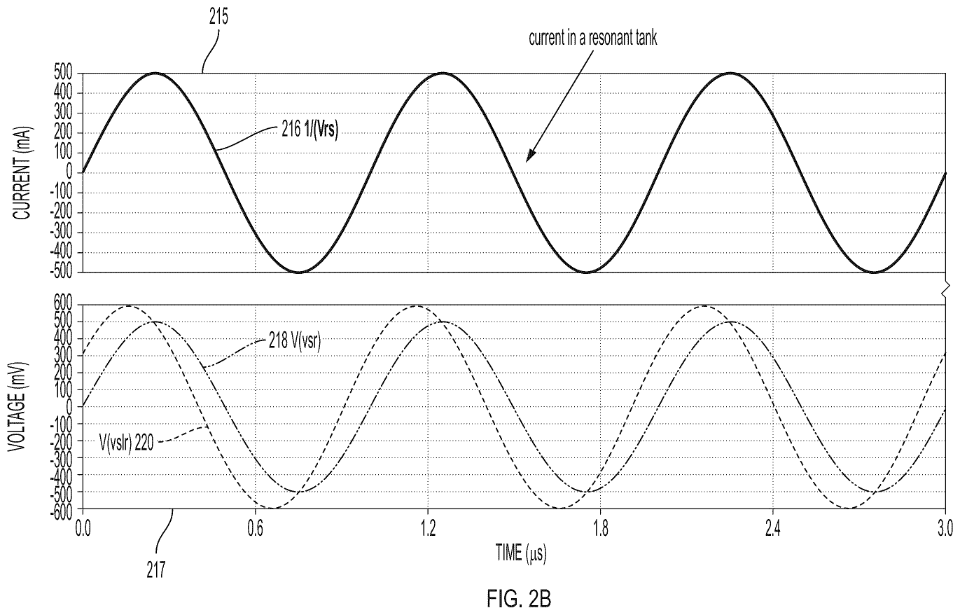

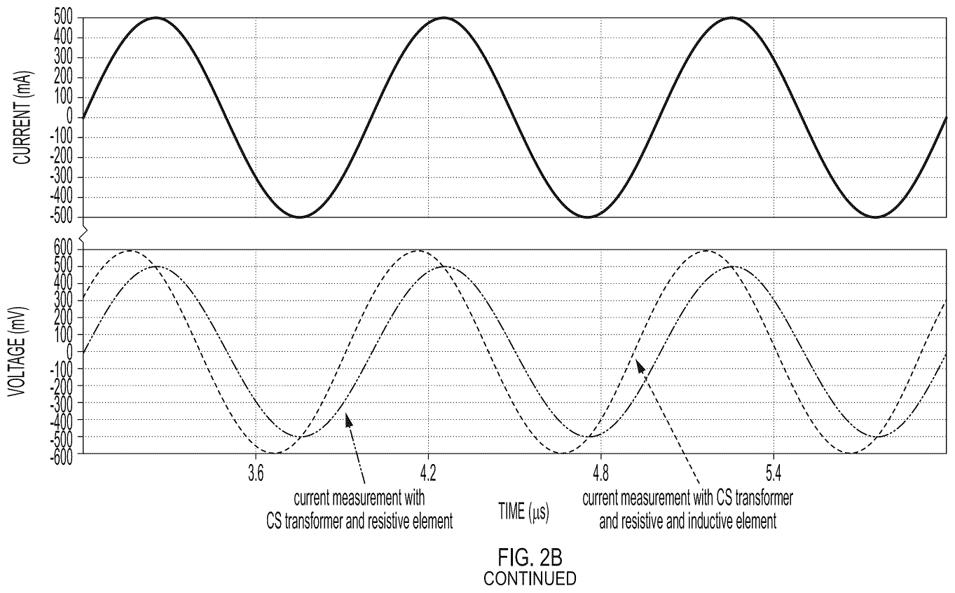

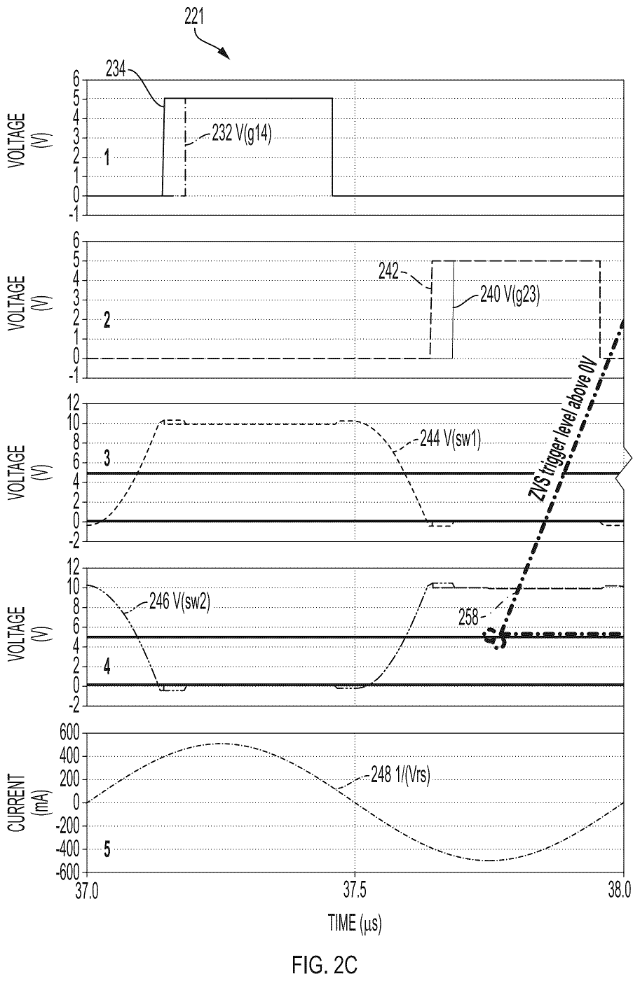

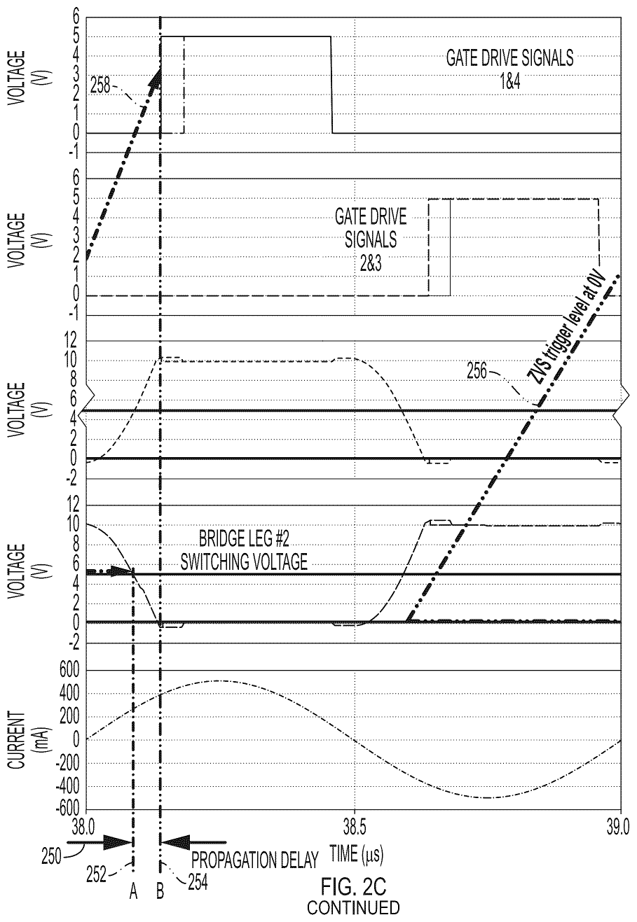

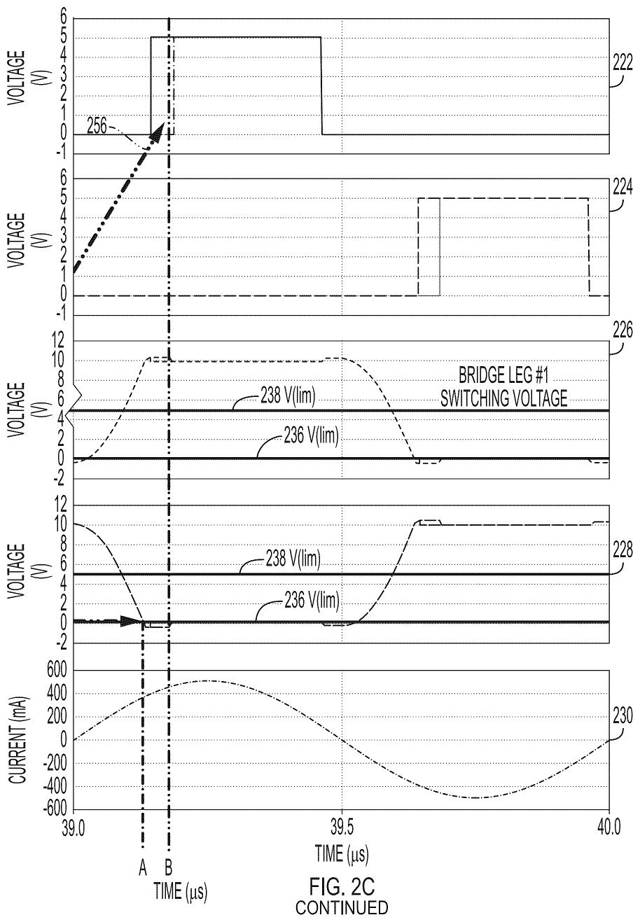

FIG. 2A is a schematic illustration of an example implementation of the measurement and phase compensation circuitry 120, which is a portion of the control circuitry 118 of FIG. 1. The measurement and phase compensation circuitry 120 of the illustrated example of FIG. 2A includes an example current sensor 202. The current sensor 202 may sense a current associated with one(s) of the switches 114, 116 of the power switch circuitry 112 of FIG. 1. For example, the current sensor 202 may sense a current at a node of the power switch circuitry 112.

The current sensor 202 of the illustrated example of FIG. 2A is a current sense transformer. A primary winding (not shown) of the current sense transformer may be wrapped around a conductor through which a current is to be measured. The secondary of the current sense transformer is shown in FIG. 2A Alternatively, the current sensor 202 may be any other type of sensor used to sense and/or measure current.

In some examples, the current sensor 202 may be replaced with a Rogowski coil that senses current through one(s) of the switches 114, 116. A Rogowski coil is a device that produces a voltage output proportional to a first derivative of the sensed current. When a Rogowski coil is used, an integrator device may be used to convert the voltage output from the Rogowski coil to a voltage signal that is proportional to the current sensed by the current sensor 202. In such an example, a non-ideal integrator can provide the desired phase shift. For example, the phase compensation network 204 may be implemented by a non-ideal integrator to generate and/or output the desired phase shift of the sensed current.

The measurement and phase compensation circuitry 120 includes an example phase compensation network 204 to adjust, change, or shift a phase of a signal, such as a sensed current, a measured current, etc., from an output of the current sensor 202. The phase compensation network 204 may be implemented by phase compensation network circuitry that shifts a phase of a sensed current from the current sensor 202 to generate and/or output a phase shifted sensed current. The phase compensation implemented by the phase compensation network 204 may be complete or partial, as the techniques disclosed herein are not limited to complete compensation.

The phase compensation network 204 in this example is implemented by an example inductance 206, which may be selected to cause the phase shift of the output of the current sensor 202 to compensate for signal chain delay(s). The inductance 206 may be a series or parallel inductance. For example, the inductance 206 may be implemented by any suitable inductor. In some examples, the inductance 206 may be an effective inductance implemented by two or more inductors arranged in series or parallel to achieve the effective inductance. Additionally or alternatively, the phase compensation network 204 may be implemented by any other component(s), such as one or more capacitors, or a combination of components, such as one or more inductors and one or more capacitors. Input(s) of the phase compensation network 204 is/are coupled to respective output(s) of the current sensor 202. In an example in which the inductance 206 is implemented by an inductor, a first end of the current sensor 202 may be coupled to a first end of the inductor. In some examples, the phase compensation network 204 may be implemented by the current sensor 202, without the need for separate component(s) to implement the phase compensation network 204. For example, the inductance illustrated by 206 may be implemented by a magnetizing inductance of a transformer that performs the current measurement, such as the current sense transformer discussed above as an example of current sensor 202.

The measurement and phase compensation circuitry 120 includes an example sense resistor 208 and an example comparator 210. The resistor 208 is a sense resistor that converts the phase shifted sensed current from the inductance 206, and/or, more generally, the phase compensation network 204, to an example sense voltage 212 (identified by V_{SENSE}). For example, the sense voltage 212 may correspond to and/or be proportional to the phase shifted sensed current. A first end of the resistor 208 is coupled to an output of the phase compensation network 204. A second end of the resistor 208 is coupled to a second end of the current sensor 202. In an example in which the inductance 206 is implemented by an inductor, the first end of the resistor 208 may be coupled to a second end of the inductor.

Comparison circuitry 210 may receive the phase-compensated sense voltage Vsense and compare it to a threshold to determine whether to activate drive circuitry 122 to turn off one or more switches of the power switch circuitry 112. The comparison circuitry 210 of the illustrated example of FIG. 2A may be implemented by a comparator, as shown in FIG. 2A. The comparator may include a first comparator input receiving Vsense, a second comparator input receiving a threshold voltage, and a comparator output coupled to drive circuitry 122. The first comparator input is coupled to the first end of the resistor 208. The second comparator input is coupled to an example terminal 214. The terminal 214 is adapted to generate and/or maintain a reference or threshold voltage. In some examples, the threshold voltage is 0 Volts (V). Alternatively, the threshold voltage may be any other voltage. The comparator output is coupled to input(s) of drive circuitry, such as input(s) of the drive circuitry 122 of FIG. 1.

In example operation, the current sensor 202 senses or measures current flowing through one of the switches 114, 116 of FIG. 1. The inductance 206, which is in series with the current sensor 202 and the resistor 208, causes a shift of a phase (i.e., a phase shift) of the sensed current in a phase leading direction. For example, the inductance 206 may generate a phase shifted sensed current by shifting the phase of the sensed current in the leading direction. Advantageously, the shift of phase in the leading direction can compensate for delay in the measurement signal chain, such as delay between the current sensor 202, the sense resistor 208, and/or the comparator 210.

In example operation, the resistor 208 generates the sense voltage 212 based on the phase shifted sensed current. The comparator may compare the sense voltage 212 to the threshold voltage present at the terminal 214. The comparator may generate an output signal based on the comparison. For example, the comparator may output a signal of a first logic level when Vsense is above the threshold and a second logic level when Vsense is below the threshold. The output of the comparator may switch from the first logic level to the second logic level in response to Vsense going below a threshold. In response to the change in output signal from the comparator, the drive circuitry 122 may turn off one(s) of the switches 114, 116. Accordingly, the synchronous rectifier may be switched with improved efficiency by shifting the switch times in a leading direction to compensate for delays in the signal chain.

FIG. 2B illustrates plots of current and voltage waveforms showing how a current measurement may be phase-shifted in a leading direction. FIG. 2B depicts example current plots 215 and voltage plots 217. Current plot 215 shows an example of a current waveform 216 corresponding to a current to be measured, such as the current through a switch in a synchronous rectifier. Voltage plot 217 shows voltage waveforms 218 and 220. Voltage waveform 218 is an example of a voltage waveform corresponding to the measurement of current waveform 216 without phase compensation, such as would be produced at Vsense (FIG. 2A) without phase compensation network 204. Waveform 220 is an example of a voltage waveform for the case in which in which phase compensation shifts the measured voltage waveform in the leading direction, as with the inclusion of phase compensation network 204 as illustrated in FIG. 2A, and a second example plot 217, which depicts a second example waveform 218 and a third example waveform 220. Although particular values of voltage and current, as well as waveform periods/frequencies and phase shift values are illustrated, this is an example, and it should be appreciated the techniques described herein are not limited to particular values of voltage and current, as well as waveform periods/frequencies or phase shift values. The voltage values may correspond to and/or may be proportional to values of current flowing through the measurement and phase compensation circuitry 120 of FIG. 2A. For example, the voltage values of the voltage waveform 220 may correspond to and/or may be proportional to values of current that flow through a circuit that includes a current sense transformer, such as the current sensor 202 of FIG. 2A, a resistive element, such as the resistor 208 of FIG. 2A, and an inductive element, such as the inductance 206 of FIG. 2A.

In the illustrated example of FIG. 2B, the voltage waveform 220 is out of phase with the current waveform 216 and the voltage waveform 218. For example, the addition of the inductance 206 of FIG. 2A shifts the phase of the voltage waveform 218 in a leading direction to result in the phase of the voltage waveform 220. Advantageously, a power switch in a synchronous rectifier may be turned off based on the third waveform 220, which is phase shifted in the leading direction relative to the second waveform 218, to turn off the power switch at an earlier point in time to compensate for the delay introduced in the measurement and control signal chain of the synchronous rectifier.

FIG. 2C is a timing diagram 221 that depicts example plots illustrates an example synchronous rectifier technique based on adjusting a threshold used for switching a power switch of a synchronous rectifier. For example, rather than waiting for a zero crossing of a voltage at a node or bridge leg in a synchronous rectifier, a power switch may be turned on at a small positive voltage value. Advantageously, turning on the power switch “early” relative to the measured zero crossing of the voltage may thus compensate for the delay introduced in the measurement and control signal chain of the synchronous rectifier.

The plots 222, 224, 226, 228, 230 include a first example plot 222, a second example plot 224, a third example plot 226, a fourth example plot 228, and a fifth example plot 230. The first plot depicts a first example waveform 232 and a second example waveform 234 illustrated with respect to an x-axis of time values and a y-axis of voltage values.

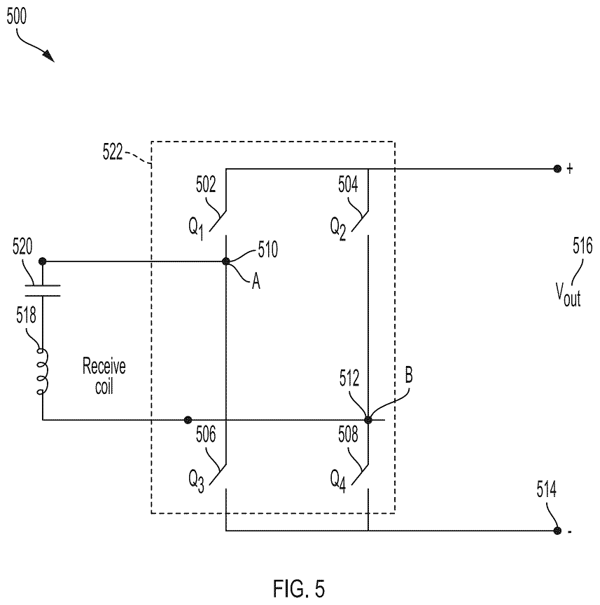

The first waveform 232 is representative of a first gate drive voltage that controls switching (e.g., turning on, turning off, etc.) of a first power switch and a fourth power switch of a synchronous rectifier. The first gate drive voltage may implement a first gate drive signal (identified by GATE DRIVE SIGNAL 1 in FIG. 2C) that controls a first example power switch 502 (identified by Q₁ in FIG. 5). The first gate drive voltage may implement a second gate drive signal (identified by GATE DRIVE SIGNAL 4 in FIG. 2C) that controls a fourth example power switch 508 (identified by Q₄ in FIG. 5) of FIG. 5. The first waveform 232 is representative of the first gate drive voltage utilized when a ZVS trigger level of the synchronous rectifier is configured and/or set to a first example threshold voltage 236, which is 0V in this example.

The second waveform 234 is representative of a second gate drive voltage that controls switching of the first power switch and the fourth power switch of the synchronous rectifier when the ZVS trigger level is configured and/or set to a second example threshold voltage 238 that is a relatively small positive voltage, which in this example is 5V. Alternatively, the second threshold voltage 238 may be a different voltage (e.g., 0.5V, 1V, 2V, etc.). In some examples, the second waveform 234 may be representative of the first gate drive signal that controls the first power switch 502 of FIG. 5. In some examples, the second waveform 234 may be representative of the fourth gate drive signal that controls the fourth power switch 508 of FIG. 5.

The second plot 224 depicts a third example waveform 240 and a fourth example waveform 242 illustrated with respect to the x-axis of time values and the y-axis of voltage values. The third waveform 240 is representative of a third gate drive voltage that controls switching of a second power switch and a third power switch of the synchronous rectifier when the ZVS trigger level is configured and/or set to the first threshold voltage 236. For example, the third gate drive voltage may implement a second gate drive signal (identified by GATE DRIVE SIGNAL 2 in FIG. 2C) that controls a second example power switch 504 (identified by Q₂ in FIG. 5). The third gate drive voltage may implement a third gate drive signal (identified by GATE DRIVE SIGNAL 3 in FIG. 2C) that controls a third example power switch 506 (identified by Q₃ in FIG. 5) of FIG. 5.

The fourth waveform 242 is representative of a fourth gate drive voltage that controls switching of the second power switch and the third power switch of the synchronous rectifier when the ZVS trigger level is configured and/or set to the second threshold voltage 238. In some examples, the fourth waveform 242 may be representative of the second gate drive signal that controls the second power switch 504 of FIG. 5. In some examples, the fourth waveform 242 may be representative of the third gate drive signal that controls the third power switch 506 of FIG. 5. In some examples, the non-zero ZVS trigger level associated with the second waveform 234 and the fourth waveform 242 are the same while in other examples they may be different.

The third plot 226 depicts a fifth example waveform 244, the first threshold voltage 236, and the second threshold voltage 238 illustrated with respect to the x-axis of time values and the y-axis of voltage values. The fifth waveform 244 is representative of a first bridge leg switching voltage of the synchronous rectifier. For example, the fifth waveform 244 may be representative of a voltage sensed at a second node 512 (identified by B in FIG. 5) of FIG. 5. The voltage sensed at the second node 512 is relative to a negative terminal 514 of an output voltage 516 (identified by V_{OUT}) of FIG. 5.

The fourth plot 228 depicts a sixth example waveform 246, the first threshold voltage 236, and the second threshold voltage 238 illustrated with respect to the x-axis of time values and the y-axis of voltage values. The sixth waveform 246 is representative of a second bridge leg switching voltage of the synchronous rectifier. For example, the sixth waveform 246 may be representative of a voltage sensed at a first node 510 (identified by A in FIG. 5) of FIG. 5. The voltage sensed at the first node 510 is relative to the negative terminal 514 of FIG. 5.

The fifth plot 230 depicts a seventh example waveform 248 illustrated with respect to the x-axis of time values and a y-axis of current values. The current values of the y-axis of the fifth plot 230 are represented in mA. In some examples, the seventh waveform 248 is representative of current through an example receive coil 518 and an example capacitor 520 as depicted in FIG. 5.

Example operation of a system illustrated by the plots 222, 224, 226, 228, 230 of FIG. 2C has a propagation delay 250, which is defined by a time difference between dashed line A 252 and dashed line B 254. For example, the propagation delay 250 may be a time difference between (i) a first time at which a threshold voltage, such as the first threshold voltage 236 or the second threshold voltage 238, is breached and (ii) a second time at which a gate drive signal is generated in response to the breach.

In example operation of the system without phase compensation, one(s) of the power switches of the system, such as the power switches 502, 504, 506, 508 of FIG. 5, may be triggered (i.e., turned on to conduct current) when a bridge leg switching voltage reaches and/or drops below the first threshold voltage 236 (identified by arrows 256 on the right side of FIG. 2C). In such example operation, the gate drive signals represented by the first waveform 232 turn on after the propagation delay 250, which reduces power efficiency of the system. For example, diodes of a diode-based rectifier may unnecessarily conduct during the period defined by the propagation delay 250, which causes extra power loss. Advantageously, if triggering is performed earlier (as identified by arrows 258 on the left side of FIG. 2C), the gate drive signals change at or near the time the switching voltages (e.g., the bridge leg switching voltages) cross zero and thereby minimizes and/or otherwise reduces the time the conductive components of the system conduct.

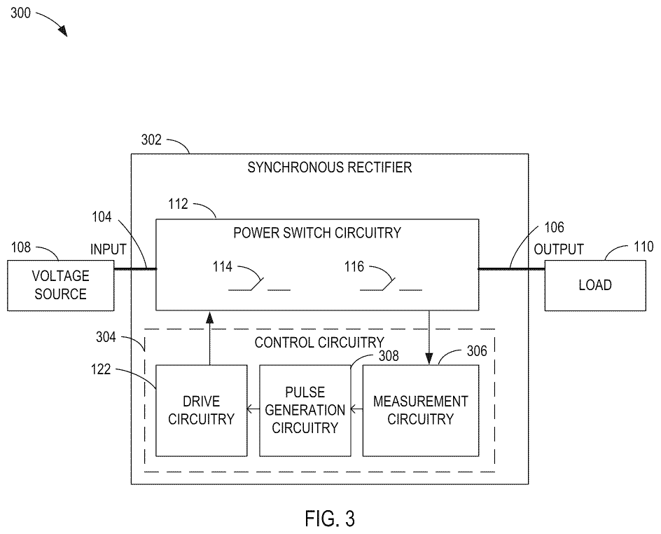

FIG. 3 is a schematic illustration of another example power conversion system 300 including an example synchronous rectifier 302. The power conversion system 300 includes the input 104, the output 106, the voltage source 108, and the load 110 of FIG. 1. The synchronous rectifier 302 includes the power switch circuitry 112, which includes the switches 114, 116 of FIG. 1, and example control circuitry 304.

The control circuitry 304 includes example measurement circuitry 306, example pulse generation circuitry 308, and the drive circuitry 122 of FIG. 1. Output(s) of the power switch circuitry 112 is/are coupled to input(s) of the measurement circuitry 306. Output(s) of the measurement circuitry 306 is/are coupled to respective input(s) of the pulse generation circuitry 308. Output(s) of the pulse generation circuitry 308 is/are coupled to respective input(s) of the drive circuitry 122. Output(s) of the drive circuitry 122 is/are coupled to respective input(s) of the power switch circuitry 112.

In example operation, one(s) of the switches 114, 116 may be turned on based on a pulse with a fixed output pulse timing. By way of example, the measurement circuitry 306 may sense a current flowing through one of the switches 114, 116. The measurement circuitry 306 may convert the sensed current to a voltage. The measurement circuitry 306 may generate an output signal representative of a determination that the voltage satisfies a threshold voltage, which may be a non-zero threshold voltage. In response to the output signal, the pulse generation circuitry 308 may generate a pulse with a fixed output pulse timing. For example, the pulse generation circuitry 308 may be implemented by single-shot circuitry.

In some examples, the pulse generation circuitry 308 may be implemented by a monostable multivibrator (MMV). For reference, an MMV is a signal conditional circuit element with (at minimum) a single input and a single output, with the following characteristics: the input and the output signals typically have two distinct voltage levels; and a voltage pulse on the input of the MMV produces a fixed length pulse on the output of the MMV, regardless of the input pulse duration. In response to the fixed length pulse on the output of the pulse generation circuitry 308, the drive circuitry 122 may turn on one(s) of the switches 114, 116 to convert the input 104 to the output 106.

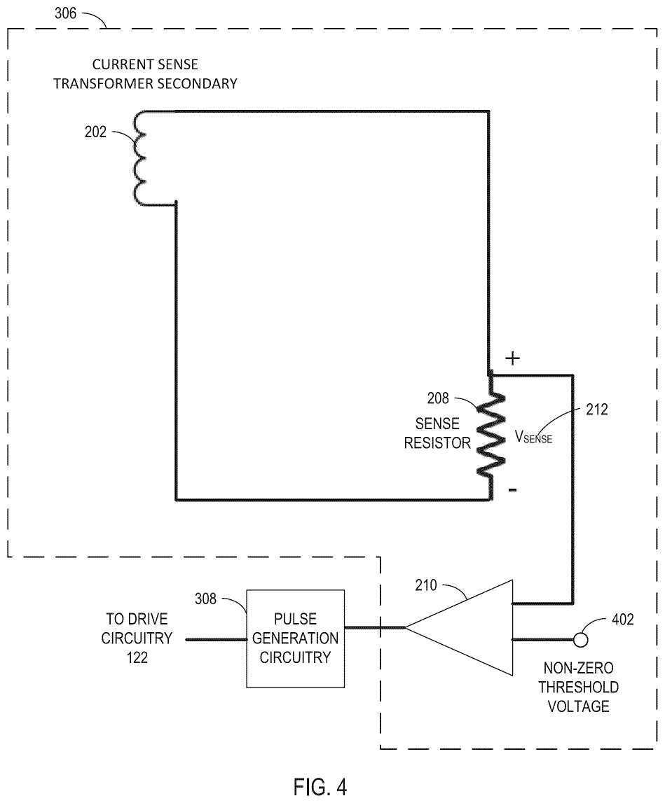

FIG. 4 is a schematic illustration of an example implementation of the measurement circuitry 306 of FIG. 3, which is a portion of the control circuitry 304 of FIG. 3. The measurement circuitry 306 of the illustrated example of FIG. 4 includes the current sensor 202, the resistor 208, the comparison circuitry 210 (e.g., a comparator), and the sense voltage 212 of FIG. 2A. The implementation of the measurement circuitry 306 as depicted in FIG. 4 omits the phase compensation network 204 and the inductance 206 of FIG. 2A. The implementation of the measurement circuitry 306 as depicted in FIG. 4 has a threshold voltage at a terminal 402 coupled to an input of the comparison circuitry 210 that is non-zero. The implementation of the measurement circuitry 306 as depicted in FIG. 4 includes an output of the comparison circuitry 210 that is coupled to an input of the pulse generation circuitry 308.

In example operation, the current sensor 202 may sense a current associated with one(s) of the switches 114, 116 of FIG. 3. The sensed current may be converted to the sense voltage 212 across the resistor 208. The comparison circuitry 210 may compare the sense voltage 212 to the non-zero threshold voltage present at the terminal 402. The comparison circuitry 210 may change the logic level of its output when the sense voltage 212 falls below the non-zero threshold voltage. In response to the signal, the pulse generation circuitry 308 may generate a pulse (e.g., a pulse or pulsed signal) with fixed timing. In response to the pulse with fixed timing, the drive circuitry 122 may control switching of one(s) of the switches 114, 116.

FIG. 5 is a schematic illustration of an example implementation of a wireless power receiver 500 as one example of an application of a synchronous rectifier. Power can be transmitted wirelessly from a wireless power transmitter (not shown) to the wireless power receiver 500 using electromagnetic induction. An alternating current is driven through a transmit coil of the wireless power transmitter, which produces a magnetic field that induces an alternating current in the receive coil 518 of the wireless power receiver 500. The received signal may then be rectified (e.g., by a synchronous rectifier 522) and further processed.

The wireless power receiver 500 includes the receive coil 518, the capacitor 520 connected in series with the receive coil 518, and the synchronous rectifier 522. The synchronous rectifier 522 is a full-bridge synchronous rectifier having the switches 502, 504, 506, 508 (identified by Q₁-Q₄).

However, the methods and circuits disclosed herein are not limited to synchronous rectifiers for wireless power receivers, as they may be applied in any suitable application. Further, the synchronous rectifier 522 is not limited to a full-bridge synchronous rectifier, as in some cases the synchronous rectifier 522 may be a half-bridge rectifier. The nominal operation of the synchronous rectifier 522 is to convert an input voltage, such as an AC voltage, to the output voltage 516, such as a DC voltage, which may be supplied to a load, such as a battery or any other component and/or circuitry. The nominal operation of the synchronous rectifier 522 of FIG. 5 is to turn on the first switch 502 and the fourth switch 508 during the half-cycles when the input voltage of the synchronous rectifier 522 is positive (while keeping the second switch 504 and the third switch 506 turned off), and to turn on the second switch 504 and the third switch 506 during the half-cycles when the input voltage of the rectifier is negative (while keeping the first switch 502 and the fourth switch 508 turned off).

In some examples, a current at the first node 510 or the second node 512 may be sensed by the measurement and phase compensation circuitry 120 of FIG. 1 to phase shift the sensed current to compensate for delay in a signal chain of the synchronous rectifier 522. For example, the synchronous rectifier 522 may be implemented by and/or correspond to the synchronous rectifier 102 of FIG. 1. In some examples, a current at the first node 510 or the second node 512 may be sensed by the measurement circuitry 306 of FIG. 3 to compensate for delay in a signal chain of the synchronous rectifier 522 in response to a pulse with fixed timing. For example, the synchronous rectifier 522 may be implemented by and/or correspond to the synchronous rectifier 302 of FIG. 3. Advantageously, the wireless power receiver 500 may achieve improved power efficiency by switching one(s) of the switches 502, 504, 506, 508 based on compensating delay in the signal chain of the synchronous rectifier 522 utilizing synchronous rectifier techniques as disclosed herein.

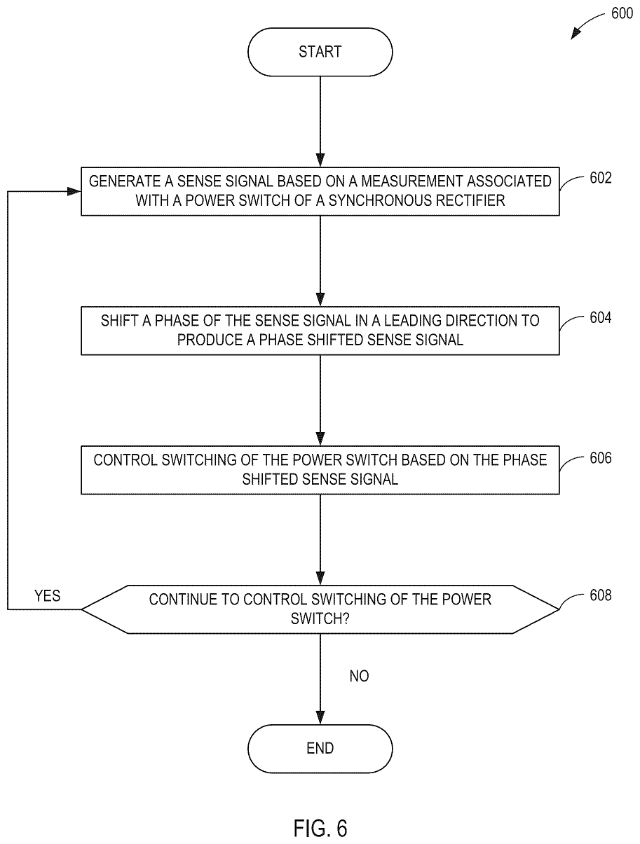

FIG. 6 is a flowchart of an example method 600 to control switching of a power switch of the synchronous rectifier 102 of FIG. 1. In some examples, the method 600 may be implemented using one or more analog circuits, one or more digital circuits, one or more programmable processors (e.g., the method 600 may be implemented as machine-readable instructions that may be executed and/or instantiated by the one or more programmable processors to carry out the operations of blocks 602, 604, 606, and 608), one or more hardware-implemented state machines, etc., and/or any combination(s) thereof.

The method 600 begins at block 602, at which a sense signal is generated based on a measurement associated with a power switch of a synchronous rectifier. For example, the current sensor 202 of FIG. 2A may generate a sense signal based on a detection and/or measurement of current through one(s) of the switches 114, 116 of FIG. 1.

At block 604, a phase of the sense signal is shifted in a leading direction to produce a phase shifted sense signal. For example, the phase compensation network 204 of FIG. 2A may shift the sense signal from the current sensor 202 in a leading direction to produce a phase shifted sense signal.

At block 606, switching of the power switch is controlled based on the phase shifted sense signal. For example, the comparator 210 of FIG. 2A may generate an output signal after a determination that the sense voltage 212 of FIG. 2A, which is proportional to the phase shifted sense signal from the phase compensation network 204, falls below the threshold voltage at the terminal 214 of FIG. 2A. In response to the output signal, the drive circuitry 122 of FIG. 1 may turn on one(s) of the switches 114, 116.

At block 608, a determination whether to continue controlling switching of the power switch is performed or carried out. For example, the synchronous rectifier 102 may continue to control the switches 114, 116 while the voltage source 108 provides the input 104. If, at block 608, the determination is to continue controlling switching of the power switch, control returns to block 602. Otherwise, the method 600 of FIG. 6 concludes.

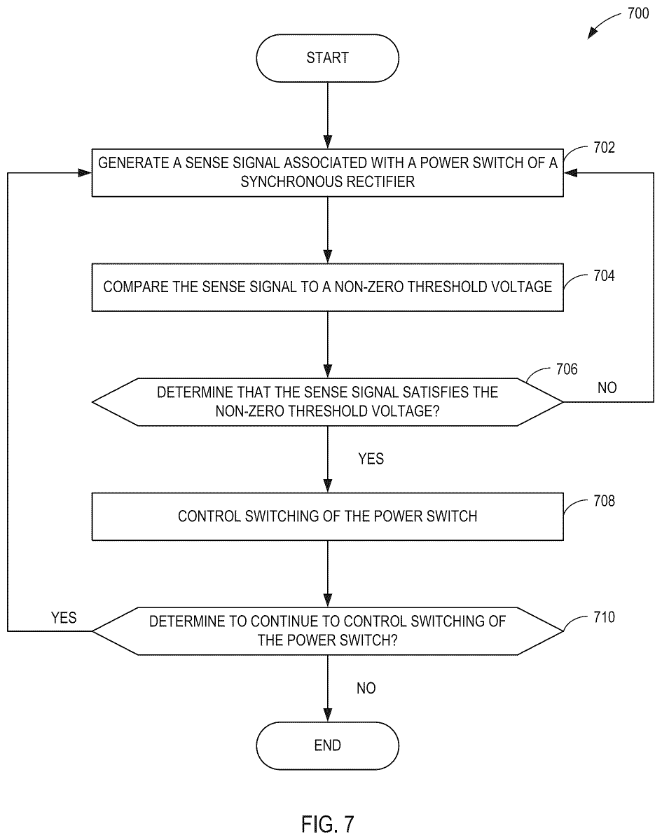

FIG. 7 is a flowchart of an example method 700 to control switching of a power switch of the synchronous rectifier 302 of FIG. 3. In some examples, the method 700 may be implemented using one or more analog circuits, one or more digital circuits, one or more programmable processors (e.g., the method 700 may be implemented as machine-readable instructions that may be executed and/or instantiated by the one or more programmable processors to carry out the operations of blocks 702, 704, 706, 708, and 710), one or more hardware-implemented state machines, etc., and/or any combination(s) thereof.

The method 700 begins at block 702, at which a sense signal associated with a power switch of a synchronous rectifier is generated. For example, the current sensor 202 of FIG. 4 may generate a sense signal based on current through one(s) of the switches 114, 116 of FIG. 3, a voltage across the one(s) of the switches 114, 116, etc.

At block 704, the sense signal is compared to a non-zero threshold voltage. For example, the comparator 210 of FIG. 4 may compare the sense voltage 212 of FIG. 2A, which is proportional to the sense signal from the current sensor 202, to the non-zero threshold voltage at the terminal 402 of FIG. 4.

At block 706, a determination whether the sense signal satisfies the non-zero threshold voltage is performed or carried out. For example, the comparator 210 of FIG. 4 may generate an output signal after a determination that the sense voltage 212, falls below the non-zero threshold voltage.

If, at block 706, the determination is that the sense signal does not satisfy the non-zero threshold voltage, control returns to block 702. Otherwise, control proceeds to block 708.

At block 708, switching of the power switch is controlled. For example, in response to the output signal, the pulse generation circuitry 308 may generate a pulse with fixed timing. In response to the pulse with fixed timing, the drive circuitry 122 of FIG. 3 may turn on one(s) of the switches 114, 116.

At block 710, a determination whether to continue controlling switching of the power switch is performed or carried out. For example, the synchronous rectifier 302 may continue to control the switches 114, 116 while the voltage source 108 provides the input 104. If, at block 710, the determination is to continue controlling switching of the power switch, control returns to block 702. Otherwise, the method 700 of FIG. 7 concludes.

Having thus described several aspects of at least one embodiment of this disclosure, it is to be appreciated that various alterations, modifications, and improvements will readily occur to those skilled in the art.

Such alterations or modifications are intended to be part of this disclosure and are intended to be within the spirit and scope of the disclosure. Further, though advantages of the present disclosure are indicated, it should be appreciated that not every embodiment of the disclosure will include every described advantage. Some embodiments may not implement any features described as advantageous herein. Accordingly, the foregoing description and drawings are by way of example only.

Various aspects of the present disclosure may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. Control circuitry for a synchronous rectifier, the control circuitry comprising:
a sensor configured to sense a current through a power switch of the synchronous rectifier, a voltage across the power switch, or a current or voltage related to the current through the power switch or the voltage across the power switch;
a phase compensation network coupled to an output of the sensor, the phase compensation network being configured to shift a phase of the output of the sensor in a leading direction to generate a phase-shifted sense signal; and
drive circuitry configured to control switching of the power switch based on the phase-shifted sense signal.

2. The control circuitry of claim 1, wherein the sensor comprises a current sensor and the drive circuitry is configured to control turn-off timings for the power switch based on the phase-shifted sense signal.

3. The control circuitry of claim 1, further comprising comparison circuitry configured to compare the phase-shifted sense signal to a threshold voltage, and to control the drive circuitry based on the comparison between the phase-shifted sense signal and the threshold voltage.

4. The control circuitry of claim 3, wherein the comparison circuitry comprises a comparator.

5. The control circuitry of claim 1, wherein a phase shift produced by the phase compensation network is selected to compensate for a delay in a signal chain driving the power switch.

6. The control circuitry of claim 3, wherein the output is a first output, the control circuitry further comprises a resistor, the resistor comprising a first end and a second end, and the first end is coupled to a second output of the phase compensation network.

7. The control circuitry of claim 6, wherein the comparison circuitry comprises a comparator, the comparator comprising a first comparator input, a second comparator input, and a comparator output, the first comparator input being coupled to the first end of the resistor, the second comparator input being coupled to a terminal configured to receive a threshold voltage, the comparator output being coupled to an input of the drive circuitry.

8. The control circuitry of claim 1, wherein the sensor comprises a current sense transformer or a Rogowski coil.

9. Control circuitry for a synchronous rectifier, the control circuitry comprising:
a sensor configured to sense a current through a power switch of the synchronous rectifier, a voltage across the power switch, or a current or voltage related to the current through the power switch or the voltage across the power switch, to produce a sense signal;
comparison circuitry configured to compare the sense signal to a non-zero threshold value;
a pulse generator configured to generate a pulse in response to an output of the comparison circuitry; and
drive circuitry configured to control switching of the power switch in response to the pulse.

10. The control circuitry of claim 9, wherein the non-zero threshold value is selected to compensate for a delay in a signal chain driving the power switch.

11. The control circuitry of claim 9, wherein the pulse generator comprises a single-shot circuit.

12. The control circuitry of claim 9, wherein the drive circuitry is configured to control the power switch to turn on in response to the pulse.

13. The control circuitry of claim 9, wherein:
a first input of the comparison circuitry is coupled to a first output of the sensor;
a second input of the pulse generator is coupled to the output of the comparison circuitry, which is a second output;
a third input of the drive circuitry is coupled to a third output of the pulse generator; and
a fourth output of the drive circuitry is coupled to the power switch.

14. The control circuitry of claim 13, further comprising a resistor with a first end and a second end, the first end coupled to the first output of the sensor and the first input of the comparison circuitry, and the second end coupled to a fourth input of the sensor.

15. The control circuitry of claim 9, wherein the sensor is a current sensor.

16. The control circuitry of claim 15, wherein the current sensor comprises a current sense transformer or a Rogowski coil.

17. A wireless power receiver comprising the control circuitry of claim 1 and the synchronous rectifier.

18. A method of controlling a synchronous rectifier, the method comprising:
sensing a current through a power switch of the synchronous rectifier, a voltage across the power switch, or a current or voltage related to the current through the power switch or the voltage across the power switch, to produce a sense signal;
shifting a phase of the sense signal in a leading direction to produce a phase shifted sense signal; and
controlling switching of the power switch based on the phase shifted sense signal.

19. (canceled)
